(19) United States
(12) Patent Application Publication
(10) Pub. No.: US 2024/0421019 A1
(43) Pub. Date: Dec. 19, 2024

(54) ELECTRONIC PACKAGE WITH REDISTRIBUTION LAYER PLATE FORMED VIA TEMPORARY PLUG

(71) Applicant: Microchip Technology Incorporated, Chandler, AZ (US)

(72) Inventor: Mankit Lam, Colorado Springs, CO (US)

(73) Assignee: Microchip Technology Incorporated, Chandler, AZ (US)

(21) Appl. No.: 18/393,114

(22) Filed: Dec. 21, 2023

Related U.S. Application Data
(60) Provisional application No. 63/521,291, filed on Jun. 15, 2023.

(51) Int. Cl. H01L 23/31; H01L 21/56; H01L 23/495

(52) U.S. Cl. CPC H01L 23/3157; H01L 21/565; H01L 23/49503

(57) ABSTRACT

Electronic packages comprising: a die with a bond pad, a mold compound encapsulating at least exposed surfaces of the die surrounding the bond pad, and a unitary redistribution layer plate on at least a portion of the mold compound and extending through the mold compound in electrical communication with the bond pad. A method comprising: depositing a plug on a die bond pad, encapsulating a proximal end of the plug and at least a portion of the die proximate the proximal end of the plug with a mold compound, removing the plug from the bond pad to form an opening in the mold compound, and depositing a redistribution layer plate on the mold compound and in the opening in the mold compound on the bond pad.

### PRIORITY

This application claims priority to U.S. Provisional Patent Application No. 63/521,291, filed Jun. 15, 2023, the contents of which are hereby incorporated in their entirety.

### TECHNICAL FIELD

The present disclosure relates to chip-size electronic packages for fan-out wafer level packaging (FOWLP) and panel-level packaging (PLP) applications, in particular, electronic packages with a unitary redistribution layer plate in contact with a bond pad formed via a temporary plug.

### BACKGROUND

In fan-out wafer level packaging (FOWLP) and panel-level packaging (PLP) applications, two processes are used to make a connection between a die bond pad and a redistribution layer through a mold compound.

A first manufacturing process to make a connection between a die bond pad and a redistribution layer through a mold compound includes forming a Cu pillar bump at the die bond pad, molding a compound over the die bond pad and Cu pillar, grinding (planarizing) the compound to reveal the top of the Cu pillar, depositing a redistribution layer over the exposed top of the Cu pillar and the compound, and laminating the backside of the die with more of the compound.

A second manufacturing process to make a connection between a die bond pad and a redistribution layer through a mold compound includes molding a compound over the die, laser drilling a hole through the compound at the die bond pad, seeding a metal+Cu plate in the laser drilled hole, grinding the mold compound and seeded metal plate to planarize the top surface, depositing a redistribution layer over the exposed top of the Cu plate and the compound, and laminating the backside of the die with more of the compound.

These processes have many steps and use specific equipment sets to support various wafer diameters. Typically, these processes support wafer diameters greater than or equal to eight inches.

There is a need for a process to manufacture chip-size electronic packages for fan-out wafer level packaging (FOWLP) and panel-level packaging (PLP) applications via fewer steps and with simpler equipment sets to form electronic packages.

### SUMMARY

Aspects provide a method comprising: depositing a first plug on a first bond pad of a die, wherein the first plug has a proximal end at the first bond pad and a distal end; encapsulating the proximal end of the first plug and at least a portion of the die proximate the proximal end of the first plug with a mold compound; removing at least a portion of the first plug from the first bond pad to form a first opening in the mold compound; and depositing a first redistribution layer plate on a portion of the mold compound and in the first opening in the mold compound on the first bond pad.

According to an aspect, there is provided an electronic package comprising: a die comprising a first bond pad; a mold compound encapsulating at least exposed surfaces of the die surrounding the first bond pad; a unitary first redistribution layer plate on at least a portion of the mold compound and extending through the mold compound in electrical communication with the first bond pad.

An aspect provides a method comprising: depositing first and second plugs on first and second bond pads of a die, respectively, wherein the first and second plugs have proximal ends at the first and second bond pads, respectively, and the first and second plugs have distal ends, respectively; encapsulating the proximal ends of the first and second plugs and at least portions of the die proximate the proximal ends of the first and second plugs with a mold compound; removing at least portions of the first and second plugs from the first and second bond pads; depositing a first redistribution layer plate on a portion of the mold compound and the first bond pad; and depositing a second redistribution layer plate on a portion of the mold compound and the second bond pad.

### BRIEF DESCRIPTION OF THE DRAWINGS

The figures illustrate examples of a process to manufacture chip-size electronic packages for fan-out wafer level packaging (FOWLP) and panel-level packaging (PLP) applications via fewer steps with simpler equipment sets to form electronic packages with a unitary redistribution layer plate in contact with a bond pad formed via a temporary plug.

FIG. 1A shows a cross-sectional, side view of a die for a chip-size electronic package.

FIG. 1B shows a cross-sectional, side view of the die of FIG. 1A, wherein a temporary plug is added to a bond pad.

FIG. 1C shows a cross-sectional, side view of the die of FIG. 1B, wherein the die package is flipped up-side-down so that the temporary plugs support the die package on a tape by pick and place.

FIG. 1D shows a cross-sectional, side view of the die of FIG. 1C, wherein the die package is overmolded with a mold compound.

FIG. 1E shows a cross-sectional, side view of the die of FIG. 1D, wherein die package is again flipped up-side-down and the tape is removed from the die package.

FIG. 1F shows a cross-sectional, side view of the die of FIG. 1E, wherein redistribution layer plates are added to a bond pad.

FIG. 1G shows a cross-sectional, side view of the die of FIG. 1F, wherein a polymer layer is applied.

FIG. 1H shows a cross-sectional, side view of the die of FIG. 1G, wherein a seed metal layer is applied.

FIG. 1I shows a cross-sectional, side view of the die of FIG. 1H, wherein a plating resist is applied to the front side of the die package.

FIG. 1J shows a cross-sectional, side view of the die of FIG. 1I, wherein package connections are built at the exposed portions of the redistribution layer plates.

FIG. 1K shows a cross-sectional, side view of the die of FIG. 1J, wherein the plating resist is stripped, the seed metal etch below the plating resist is removed, and package connections have been built at the exposed portions of the redistribution layer plates.

FIG. 2 shows a flow chart for a method for fabricating chip-size electronic packages for fan-out wafer level packaging (FOWLP) and panel-level packaging (PLP) applications.

FIG. 3 shows a cross-sectional, side view of a die package having a unitary redistribution layer plate in electrical communication with a bond pad of the die through an opening in the mold compound encapsulate.

FIG. 4 shows a flow chart for a method for fabricating chip-size electronic packages for fan-out wafer level packaging (FOWLP) and panel-level packaging (PLP) applications.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect, there is provided a photolithographic technique to form a “temporary plug” at the bond bad sites. The “temporary plug” may be removed post-molding creating an access via for the redistribution layer to contact the bond pad when it is formed.

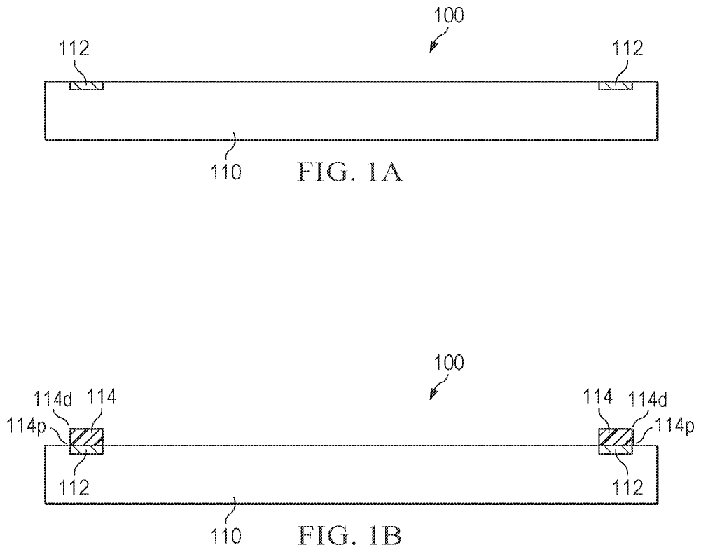

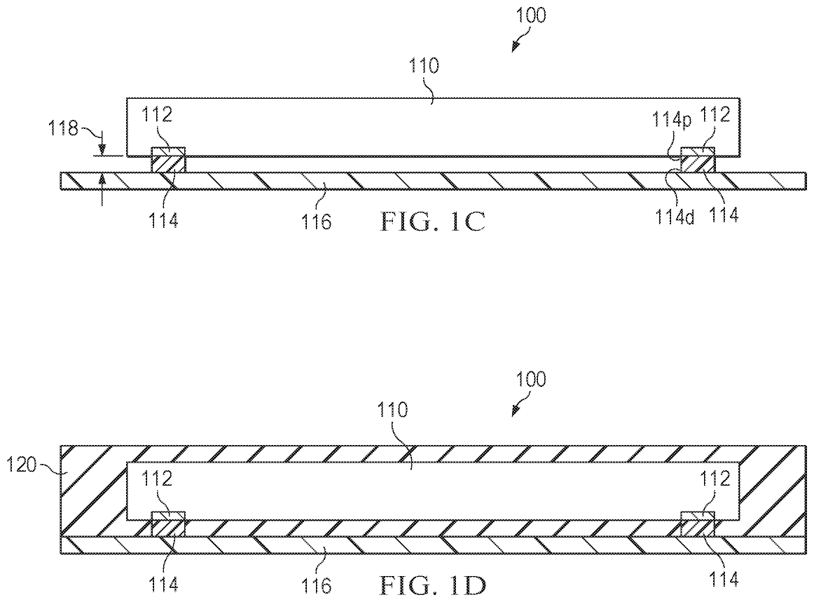

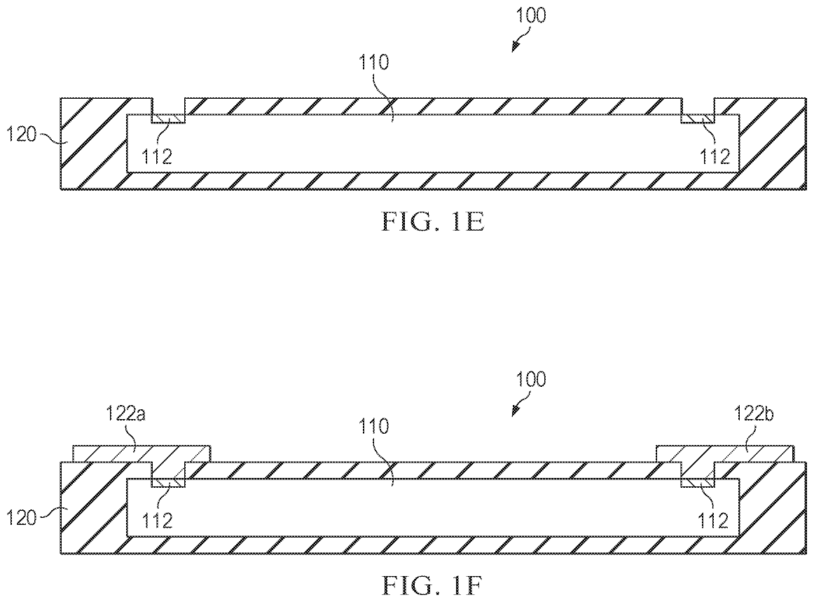

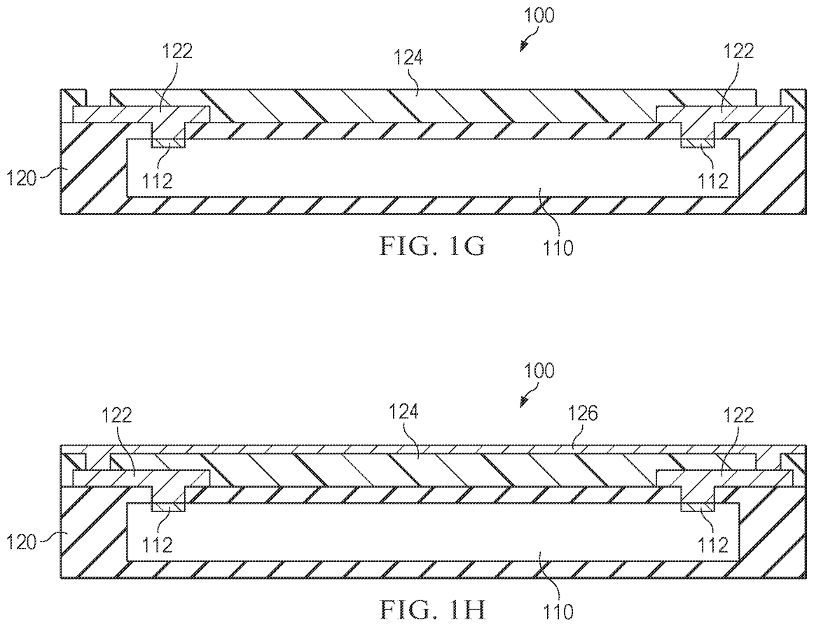

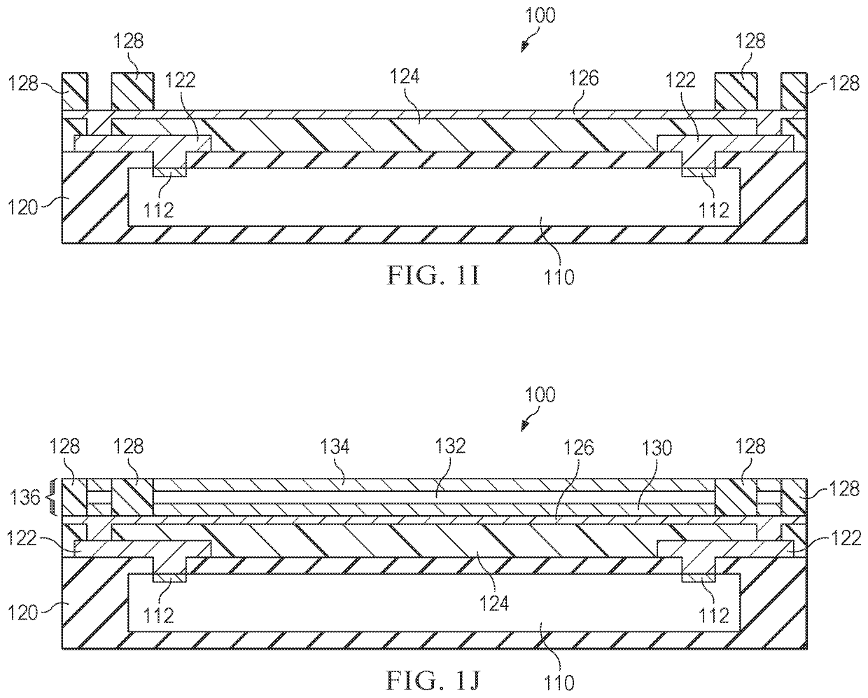

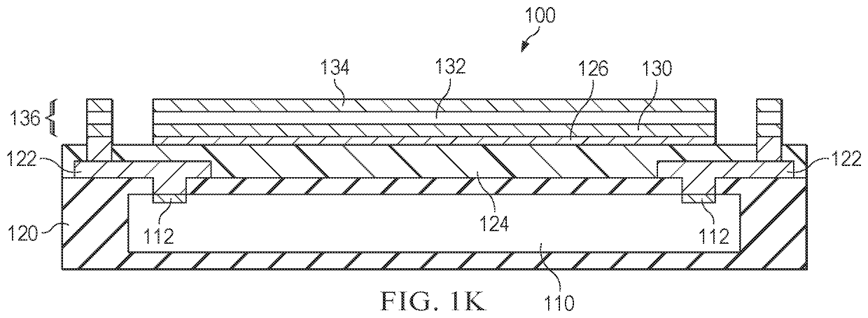

FIG. 1A shows a cross-sectional, side view of a die for a chip-size electronic package. The die 100 has a silicon layer 110 and bond pads 112. The bond pads 112 may be aluminum or any suitable material, without limitation. As shown, the active side of the die is the side where the bond pads 112 are located, which may be termed the top or up-side.

FIG. 1B shows a cross-sectional, side view of the die of FIG. 1A, wherein one or more temporary plugs 114 is added to a bond pad 112. The temporary plugs 114 may be added by a dry film photo resist. The temporary plug 114 may be deposited by: applying a film resist; applying a patterned mask to the film resist; exposing the film resist to light through the patterned mask; and removing portion of the film resist to form an opening in the remaining film resist; and depositing the temporary plug in the opening in the remaining film resist. The temporary plug 114 may comprise a polymer. A respective plug 114 may be deposited on a bond pad 112 of the die package 100, wherein the plug 114 has a proximal end 114p at the bond pad 112 and a distal end 114d.

FIG. 1C shows a cross-sectional, side view of the die of FIG. 1B, wherein the die package 100 is flipped up-side-down so that the temporary plugs 114 support the die 100 on a tape 116, wherein the die 100 is placed on tape 116 by pick and place (PnP). PnP is a process where a vacuum plunger picks up individual dies from a dicing wafer, flips them over, and places them on the tape 116 so that it is PnP attached to the tape. The tape 116 may be in contact with the distal ends 114d of the temporary plugs 114. A thickness of the temporary plugs 114 stand the silicon layer 110 off the tape 116 by a standoff distance 118 equal to the thickness of the temporary plugs 114.

FIG. 1D shows a cross-sectional, side view of the die of FIG. 1C, wherein the die 100 is overmolded with a mold compound 120. The mold compound 120 surrounds the silicon layer 110, including filling the space between the silicon layer 110 and the tape 116. Mold compound 120 may encapsulate the outer, exposed portions proximal end 114p of the plug 114 and at least a portion of the die 100 proximate the proximal end of the plug 114. Alternatively, encapsulating the die may comprise filling a portion of the space defined between the tape and the die with mold compound including space proximate a plug 114.

FIG. 1E shows a cross-sectional, side view of the die of FIG. 1D, wherein die package 100 is again flipped up-side-down. The tape 116 is removed from the die package 100 (see FIG. 1D). The die package 100 is subjected to a strip dry film resist process to remove the temporary plugs 114 (see FIGS. 1B-1D) so that the bond pads 112 are exposed through openings in the mold compound 120.

FIG. 1F shows a cross-sectional, side view of the die of FIG. 1E, wherein redistribution layer plates 122 are added to a bond pad 112. A seed metal is sputtered to adhere to the bond pads 112, a photo resist is applied to define an area for the redistribution layer plates 122, the redistribution layer plates 122 are added to a bond pad 112, and the excess seed metal is removed. The redistribution layer plates 122 may be Cu or any suitable material, without limitation. Respective ones of the redistribution layer plates 122 comprise a portion of a redistribution layer on at least a portion of the mold compound and a portion extending through the mold compound in electrical communication with a bond pad, wherein the portions are collectively “unitary” and “unitary” means the portions on the mold compound and extending through the mold compound are deposited simultaneously. The redistribution layer plates may be portions of a single, unitary redistribution layer. Alternatively, the redistribution layer plates may be separate and distinct first and second redistribution layer plates 122a and 122b, deposited simultaneously or at different times.

FIGS. 1G through 1K show cross-sectional, side views of the die 100 of FIG. 1F at various developments of building package connections to the redistribution layer plates 122, wherein the package connections may be pillar bumps.

FIG. 1G shows a cross-sectional, side view of the die of FIG. 1F, wherein a polymer layer 124 is applied by deposition. The polymer layer 124 may be a polyimide (PI) or a polybenzoxazole (PBO). A portion of the redistribution layer plate 122 is exposed through the polymer layer 124 to provide places for package connections to be built in contact with the redistribution layer plates 122. The package connections may be pillar bumps.

FIG. 1H shows a cross-sectional, side view of the die 100 of FIG. 1G, wherein a first seed metal layer 126 is applied. The first seed metal layer 126, which may be a Ti—Cu layer 126, may be applied by sputtering, and is applied to the front side of the die 100 on top of the polymer layer 124 and the exposed portions of the redistribution layer plates 122.

FIG. 1I shows a cross-sectional, side view of the die of FIG. 1H, wherein a plating resist 128 is applied to the front side of the die package 100.

FIG. 1J shows a cross-sectional, side view of the die of FIG. 1I, wherein package connections are built at the exposed portions of the redistribution layer plates 122 through openings in the plating resist 128. A Cu layer 130 is plated on the front side of the die package 100, covering the first seed metal layer 126. A Ni layer 132 is plated on the front side of the die package 100, covering the Cu layer 130. A SnAg layer 134 is plated on the front side of the die package 100, covering the Ni layer 132. These layers may form package connections 136.

FIG. 1K shows a cross-sectional, side view of the die of FIG. 1J, wherein the plating resist 128 is stripped and the seed metal below the plating resist 128 is removed with a stripping solution, which may comprise a NaOH solution. Package connections 136 have been built at the exposed portions of the redistribution layer plates 122.

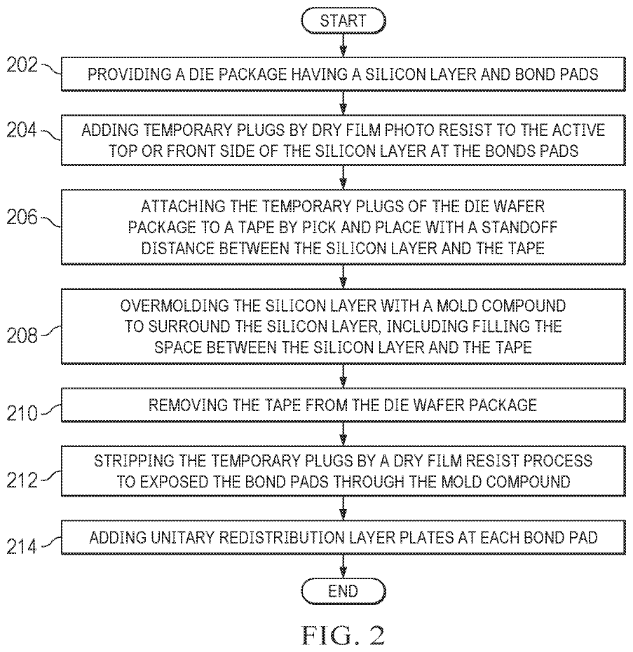

FIG. 2 shows a flow chart for a method for fabricating chip-size electronic packages for fan-out wafer level packaging (FOWLP) and panel-level packaging (PLP) applications. A die 100 having a silicon layer 110 and bond pads 112 (see FIG. 1A) is provided 202. Temporary plugs 114 (see FIG. 1B) are added 204 by dry film photo resist to the active top or front side of the silicon layer 110 at the bond pads 112. The die package 100 is flipped up-side-down and the temporary plugs 114 (see FIG. 1C) are attached 206 to a tape 116 by with a standoff distance 118 between the silicon layer 110 and the tape 116. The die package 100 may be attached to a tape by a pick and place (PnP) process or machine. The silicon layer is overmolded with an mold compound 120 (see FIG. 1D to surround the silicon layer 110, including filling the space between the silicon layer 110 and the tape 116. The tape 116 is removed 210 from the die package 100 (see FIG. 1E). The temporary plugs 114 are stripped 212 to expose the bond pads 112 (see FIG. 1E) through the mold compound 120. Removal may be by a dry film resist process. Redistribution layer plates 122 (see FIG. 1F) are added at respective ones of bond pads 112, wherein portions of the redistribution layer plates 122 contact the bond pads 112.

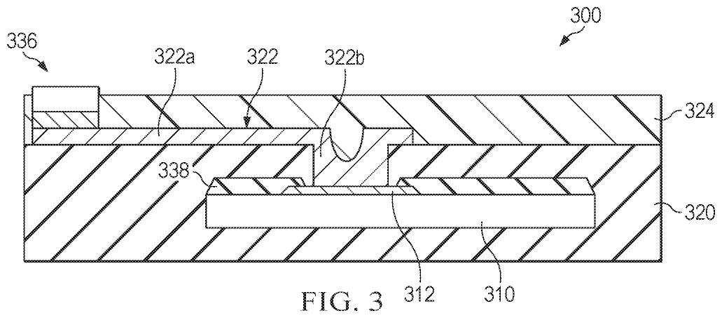

FIG. 3 shows a cross-sectional side view of a chip-size electronic package 300 for fan-out wafer level packaging (FOWLP) and panel-level packaging (PLP) applications. In the interior of the package 300, there is a die 310 with its active side “up” (front side). The die 310 has a bond pad 312, made of metal. The die 310 also has a passivation layer 338 on its front side around the bond pad 312. A mold compound 320 encapsulates exposed surfaces of the die 312. A unitary redistribution layer plate 322 is applied with a portion in contact with the bond pad 312 and a portion on the mold compound 320 proximate the bond pad 312. A polymer layer 324 is applied over the unitary redistribution layer plate 322, wherein a package connection 336 in the form of a pillar bump may be formed to contact the redistribution layer plate 322. The package connection 336 may be formed as a Cu layer, a Ni layer, and a SnAg layer, or any combination of these layers.

The chip-size electronic package 300 shown in FIG. 3 may be identified as manufactured by processes described herein by either: (1) the unitary redistribution layer plate 322 having no internal inconsistencies, or (2) a mold compound, as will be described further.

First, the unitary redistribution layer plate 322 has no internal inconsistencies because it is laid down in one step of the process. The unitary redistribution layer plate 332 may have a first portion 322a on the mold compound 320 proximate the bond pad 312 and a second portion 322b extending through an opening in the mold compound 320 and in contact with the bond pad 312, wherein the first and second portions 322a and 322b are unitary. In prior processes, a pillar is first laid down and then later a redistribution layer is laid down so that an inconsistency is formed between the two structures even if they are made with the same material. Further, prior processes may lay down a Cu-Titanium-Cu layer between the pillar and the redistribution layer. No such Cu-Titanium-Cu layer is located between portions of the unitary redistribution layer plate 322 shown in FIG. 3.

Second, the chip-size electronic package 300 shown in FIG. 3 has a unitary mold compound because the die is encapsulated in one step of the process. In prior process, the front side of the die is first over molded with a compound while the back side of the die is resting on a support structure and then later the back side of the die is over molded or laminated to encapsulate the die, which results in an interface between the two applications of compound even if the same compound was used in both applications. No such interface is located between portions of the mold compound 320 shown in FIG. 3.

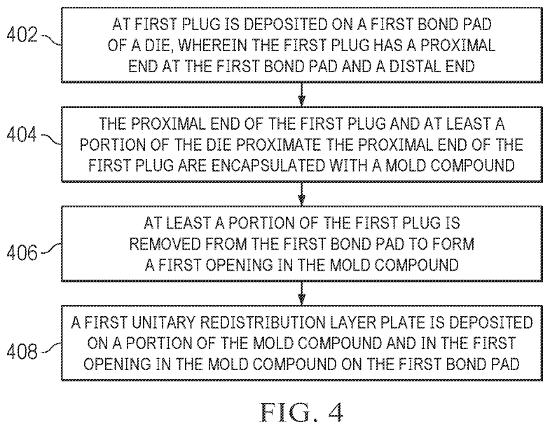

FIG. 4 shows a flow chart for a method for fabricating chip-size electronic packages. A first plug is deposited 402 on a first bond pad of a die, wherein the first plug has a proximal end at the first bond pad and a distal end. Outer portions of the proximal end of the first plug and at least a portion of the die proximate the proximal end of the first plug are encapsulated 404 with a mold compound. At least a portion of the first plug is removed 406 from the first bond pad to form a first opening in the mold compound. A first redistribution layer plate is deposited 408 on a portion of the mold compound and in the first opening in the mold compound on the first bond pad.

Although examples have been described above, other variations and examples may be made from this disclosure without departing from the spirit and scope of these disclosed examples.

1. A method comprising:
depositing a first plug on a first bond pad of a die, wherein the first plug has a proximal end at the first bond pad and a distal end;
encapsulating an outer portion of the proximal end of the first plug and at least a portion of the die proximate the proximal end of the first plug with a mold compound;
removing at least a portion of the first plug from the first bond pad to form a first opening in the mold compound; and
depositing a first unitary redistribution layer plate on a portion of the mold compound and in the first opening in the mold compound on the first bond pad.

2. The method as in claim 1, comprising;
depositing a second plug on a second bond pad of the die, wherein the second plug has a proximal end at the second bond pad and a distal end;
encapsulating an outer portion of the proximal end of the second plug and at least a portion of the die proximate the proximal end of the second plug with the mold compound;
removing at least a portion of the second plug from the second bond pad to form a second opening in the mold compound; and
depositing a second redistribution layer plate on a portion of the mold compound and in the second opening in the mold compound and on the second bond pad.

3. The method as in claim 1, comprising:
applying a film resist;
applying a patterned mask to the film resist;
exposing the film resist to light through the patterned mask; and
removing portion of the film resist to form an opening in the remaining film resist; and
wherein the depositing the first plug comprises depositing the first plug in the opening in the remaining film resist.

4. The method as in claim 1, comprising attaching tape to the distal end of the first plug so a space is defined between the die and the tape, wherein the encapsulating the die comprises filling at least a portion of the space defined between the tape and the die with mold compound.

5. The method as in claim 4, wherein the attaching tape to the distal end of the first plug comprises pick and place attaching.

6. The method as in claim 4, comprising removing the tape from the first plug and the mold compound.

7. The method as in claim 1, wherein the encapsulating the die comprises encapsulating exposed surfaces of the die.

8. The method as in claim 1, comprising applying a first package connection to the first redistribution layer plate.

9. The method as in claim 1, comprising applying a dielectric layer over the first redistribution layer plate.

10. An electronic package comprising:
a die comprising a first bond pad;
a mold compound encapsulating at least exposed surfaces of the die surrounding the first bond pad;
a first unitary redistribution layer plate on at least a portion of the mold compound and extending through the mold compound in electrical communication with the first bond pad.

11. The electronic package as in claim 10, comprising:
the die comprising a second bond pad;
the mold compound encapsulating at least exposed surfaces of the die surrounding the second bond pad; and
a second unitary redistribution layer plate on at least a portion of the mold compound and extending through the mold compound in electrical communication with the second bond pad.

12. The electronic package as in claim 10, comprising a first package connection in electrical communication with the first unitary redistribution layer plate.

13. The electronic package as in claim 11, comprising a second package connection in electrical communication with the second unitary redistribution layer plate.

14. The electronic package as in claim 12, comprising a dielectric layer on the first unitary redistribution layer plate.

15. The electronic package as in claim 13, comprising a dielectric layer on the first unitary redistribution layer plate and the second unitary redistribution layer plate.

16. A method comprising:
depositing first and second plugs on first and second bond pads of a die, respectively, wherein the first and second plugs have proximal ends at the first and second bond pads, respectively, and the first and second plugs have distal ends, respectively;
encapsulating the proximal ends of the first and second plugs and at least portions of the die proximate the proximal ends of the first and second plugs with a mold compound;
removing at least portions of the first and second plugs from the first and second bond pads; and
depositing a first unitary redistribution layer plate on a portion of the mold compound and the first bond pad; and
depositing a second unitary redistribution layer plate on a portion of the mold compound and the second bond pad.

17. The method as in claim 16, comprising:
applying a film resist to the first and second bond pads and the die;
applying a patterned mask to the film resist;
exposing the film resist to light through the patterned mask; and
removing portion of the film resist to form openings in the remaining film resist at the first and second bond pads; and
wherein the depositing first and second plugs comprises depositing first and second plugs in the openings of the remaining film resist.

18. The method as in claim 16, comprising attaching tape to the distal ends of the first and second plugs so a space is defined between the die and the tape, wherein encapsulating the die comprises filling at least a portion of the space defined between the tape and the die with mold compound.

19. The method as in claim 16, comprising: applying a first package connection to the first unitary redistribution layer plate, and applying a second package connection to the second unitary redistribution layer plate.

20. The method as in claim 16, comprising applying a polymer layer on the first and second redistribution layer plates.
